(19) United States
(12) Patent Application Publication
(10) Pub. No.: US 2018/0175276 A1
(43) Pub. Date: Jun. 21, 2018

(54) MICROFABRICATED SELF-SENSING ACTUATOR

(71) Applicant: Innovative Micro Technology, Goleta, CA (US)

(72) Inventor: Benedikt ZEYEN, Santa Barbara, CA (US)

(21) Appl. No.: 15/382,606

(22) Filed: Dec. 17, 2016

(51) Int. Cl. H01L 41/083; H01L 41/047; H01L 41/27

(52) U.S. Cl. CPC H01L 41/083; H01L 41/27; H01L 41/0471

(57) ABSTRACT

Described herein is a method and structure for fabricating a self-sensing piezoelectric actuator. In a single device, the actuator may be formed which is capable of movement, along with a sensor that may provide a signal indicative of the speed and/or magnitude of the movement. The actuator may be fabricated on one wafer, and the sensor fabricated on a second wafer, and the two wafers bonded together to form the device. The device may be appropriate for vibration devices such as ultrasound tranducers and the like. The structure may be fabricated using well known semiconductor techniques such as depositions, etching and ion implantation.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to a microfabricated actuator with integrated sensor.

Microelectromechanical systems are devices which are manufactured using lithographic fabrication processes originally developed for producing semiconductor electronic devices. Because the manufacturing processes are lithographic, MEMS devices may be made in very small sizes. MEMS techniques have been used to manufacture a wide variety of transducers and actuators, such as accelerometers and electrostatic cantilevers.

MEMS devices are often movable, and so they may be enclosed in a rigid structure, or device cavity formed between two wafers, so that their small, delicate structures are protected from shock, vibration, contamination or atmospheric conditions. Many such devices also require an evacuated environment for proper functioning, so that these device cavities may need to be hermetically sealed after evacuation. Thus, the device cavity may be formed between two wafers which are bonded using a hermetic adhesive.

A variety of movable devices may be made on a semiconductor substrate using photolithographic processes. One such device is a piezoelectric actuator. A piezoelectric material is one which develops a voltage (or potential difference) across two of its faces when compressed (useful for sensor applications), or physically changes shape when an external electric field is applied (useful for actuator applications).

So called “PZT” or lead zirconate titanate (chemical formula Pb[ZrₓTi₁₋ₓ]O₃ (0≤x≤1) is a frequently used piezoelectric material. It is an intermetallic inorganic compound having a ceramic perovskite crystal formation that shows a marked piezoelectric effect. Being piezoelectric, PZT develops a voltage (or potential difference) across two of its faces when compressed (useful for sensor applications), or physically changes shape when an external electric field is applied (useful for actuator applications). The dielectric constant of PZT can range from 300 to 3850, depending upon orientation and doping. The compound is used in a number of practical applications in the areas of robotics, electronics and electroceramics.

Measuring the amount of movement of the PZT may be done using a pressure sensor or accelerometer. Alternatively, the movement may be measured optically, by mounting a reflector on the PZT stack and measuring the displacement of a beam of light. Movements on the several micron scale can be measured using this technique. Smaller displacements may be measured using laser interferometry, for example. However, these techniques may be bulky and expensive, requiring a separate detection methodology, coherent or incoherent light source, optical reflectors and detectors, etc.

Accordingly, the sensing of PZT and other actuator movements remains an unresolved problem.

### SUMMARY

Systems and methods are described for a microfabricated self-sensing actuator structure. The actuator may use any of a number of effects to accomplish motion, such as electrostatic, electromagnetic, magnetostatic, piezoelectric. In one embodiment, the actuator may be a slab of PZT with a top and bottom electrode deposited on the obverse faces. Application of a voltage potential may cause a deflection of these surfaces via the piezoelectric effect.

The actuator deflection may then be measured by an integrated sensor formed on a substrate. The sensor may be, for example, a piezo resistive material that changes resistivity as a function of stress. When the substrate, on which this sensor is fabricated, is bonded to the actuator, the actuator may impart a stress to the substrate which is measured by the sensor. Accordingly, the device may define an integrated sensor in an integrated device. The actuator substrate and the sensor substrate may be form a device cavity, encapsulating the sensor structure in a hermetic cavity defined by the substrate surfaces and the bond lines.

Accordingly, a microfabricated self-sensing actuator may include a first substrate on which a microfabricated actuator is formed, wherein the microfabricated actuator has a portion capable of motion, and a second substrate on which a sensing structure is formed, wherein the sensing structure senses the motion of the microfabricated actuator; and wherein the first substrate is bonded to the second substrate to form a substrate pair, by a bonding material deposited on at least one of the first and the second substrate. In some embodiments, the microfabricated actuator may be a lead zirconiate titanate (PZT) slab, and the sensing structure may be a piezoresistive element formed in a silicon substrate. The PZT slab may be bonded to the sensing structure to form the self-sensing device.

These and other features and advantages are described in, or are apparent from, the following detailed description.

### BRIEF DESCRIPTION OF THE DRAWINGS

Various exemplary details are described with reference to the following figures, wherein:

FIG. 1 is a schematic cross sectional diagram of one embodiment of the integrated actuator and sensor;

FIG. 2 is a schematic plan view of one embodiment of the integrated actuator and sensor;

FIG. 3 is a schematic cross sectional diagram of another embodiment of the integrated actuator and sensor; and

FIG. 4 is a schematic cross sectional diagram of yet another embodiment of the integrated actuator and sensor.

It should be understood that the drawings are not necessarily to scale, and that like numbers may refer to like features.

### DETAILED DESCRIPTION

Described herein is a method and structure for fabricating a self-sensing actuator. In a single device, the actuator may be formed which is capable of movement, along with a sensor that may provide a signal indicative of the speed and/or magnitude of the movement. The actuator may be fabricated on one wafer, and the sensor fabricated on a second wafer, and the two wafers bonded together to form the device. The device may be appropriate for high frequency vibrational devices such as ultrasound tranducers and the like. The structure may be fabricated using well known semiconductor techniques such as deposition, etching and ion implantation.

In some embodiments, the actuator may be a PZT material, wherein a piezoelectric layer with a top electrode and a bottom electrode may be joined with a semiconductor layer, which has piezoresistive areas in certain locations. The joint between the two layers may be interrupted in those areas where the piezoresistive areas require space. The layer thicknesses may be chosen such that the piezoresistive areas experience strain when the piezoelectric layer is deformed.

In some embodiments, the piezoresistive layers that comprise the sensor may be implanted into a semiconductor substrate. The piezoresistive element may be embedded in a well implant using nitrogen implantation, and a piezoresistive element may be formed using a phosphorous implantation. The contact between metal and the piezoresistive layer may have a separate contact implantation.

The following discussion presents a plurality of exemplary embodiments of the novel self-sensing actuator device. The following reference numbers are used in the accompanying figures, to refer to the following structures:
1 first substrate
2 second substrate
5 PZT slab (may also be substrate 1)
10 top electrode
20 bottom electrode
30 bottom bond
40 implant well
50 piezoresistive element implant
60 contact implant
70 metal
80 semiconductor substrate (may also be substrate 2)

In the systems and methods described here, a self-sensing device may be fabricated on two surfaces, surface 1 and surface 2. The first surface, 1, may contain or comprise a moving actuator portion. The second surface, 2, may include or comprise a sensor sensing the motion of the actuator fabricated on the first surface, 1.

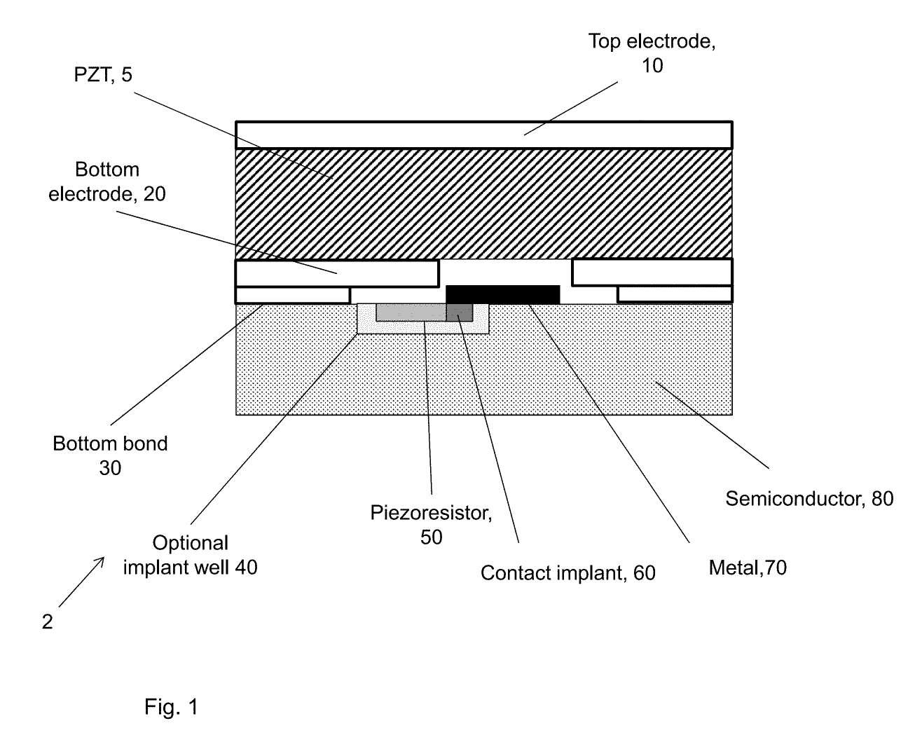

In a first exemplary embodiment shown in FIG. 1, the upper substrate or surface is a piezoelectric material, 5. This piezoelectric electric material 5 maybe for example lead zirconiate titanate (PZT) slab 5, a commonly used piezoelectric material. This material may have a preferred thickness of between about 10 to 100 μm, and may start from an as-manufactured starting thickness and be ground down to the preferred thickness.

The piezoelectric material, 5, maybe sandwiched between a top electrode 10, and a bottom electrode 20. Both the top electrode 10 and the bottom electrode 20 may further comprise a multilayer stack, including an adhesion layer, a barrier layer, and a conductive layer. As the name implies, the adhesion layer may be may assist in the adherence of the conductive material to the piezoelectric material, 5. The adhesion layer maybe for example chrome (Cr) titanium (Ti) or tantalum (Ta), and may have a thickness of between about 1 to about 50 nm. The barrier layer may be platinum, for example, and may have a thickness of about 0.1 μm. The conductive layer may be for example gold at the thickness of between 0.2 to 2 μm. The gold layer may further have a bonding material disposed thereon such as a gold/indium metal multilayer bonding material.

Accordingly, the bottom electrode 20 may function as both an electrode and as a bonding material. The constituent layers, the adhesion layer, the barrier layer, and the conductive layer may be made or deposited by, for example, chemical vapor deposition or sputtering. These layers maybe patterned if desired by the usual techniques such as photolithography, etching, or lift off.

Accordingly, the top electrode 10 may comprise a multilayer of adhesion+barrier+conductive layers, and may be, for example, CrPtAu. The bottom electrode 20 may have the same composition, but may also include an additional “trans liquid phase” metal for bonding in the areas where bonding takes place, for example Indium. This trans liquid material may be a material that goes through a melted, liquid phase before freezing when the material forms an alloy with another material.

As mentioned previously, the lower surface 2 may contain an integrated sensor, sensing the motion of the upper surface 1. The lower surface 2 may be bonded to the upper surface using the bottom bonding material 30. This bottom bonding material 30 may be made of, for example, a metal alloy such as gold/indium or gold/lead. Accordingly, the bonding methodology may be a metal alloy that is formed at relatively low temperatures. Alternatively, the bonding material 30 may be a gold thermocompression bond.

An exemplary embodiment for the architecture of the sensor is discussed next. In one embodiment, the sensor may be a piezoresistive element which is fabricated in a silicon substrate, 2. The piezoresistive element may be in an area of an implantation well 40, in the surface of the lower substrate 2. The piezoresistive element may be placed in an area of high strain, such as directly beneath the actuator. The architecture may place an emphasis on high signal and low noise, but with a focus on minimizing the size of the device, and thus its footprint on the wafer. The bond between the piezoelectric and semiconductor layer may be concentrated in all other areas, including unused high strain areas. In order to have adequate signal-to-noise, the sensing structure may need to be formed away from the neutral axis. To maximize sensitivity, sensor should be placed at least a few microns from the neutral axis, for example, about 100 microns if the application allows this. Self-evidently, the sensor will perform better the further from the neutral axis that it is placed. Both the piezoresistor and the bond surface should ideally be in high shear strain areas: The piezoresistor to get adequate sensing power, and the bond to get adequate displacement. There may be design tradeoffs in choosing allocation for the sensor and bond surface.

As shown in FIG. 1, the sensor may include an implantation well 40, a piezoresistive structure 50 and a contact implant area 60. The sensor may further include a metal structure 70 which may deliver a sensing current to the piezoresistive element 50. Each of these structures, the implantation well 40, the piezoresistive implant 50, and the contact implant 60 may be formed by ion implantation into the silicon surface. The ions may be, for example, boron, phosphorus or arsenic, as is well known in the art.

In other exemplary embodiments, the sensor may be any metal material which demonstrates a piezoresistive effect. However, silicon has advantageous piezoresistive characteristics, including a much higher piezoresistive effect.

In one embodiment, the bottom bond 30 is made from the same material and at the same time as the metal structure 70. Accordingly, they be made of the same material and may be, for example gold. These gold structures—the bottom bond 30 and metal 70 may be deposited simultaneously.

In order to form the implant well 40, the substrate may be bombarded with phosphorus or boron ions and heated until the ions are driven into the bulk. Another ion implantation may follow to form the piezoresistive element 50. Once again, the implantation may be accomplished using boron, phosphorus or arsenic ions bombardment of the surface, followed by heating, for example. The depth of the implantation may depend on the velocity and the number of ions impacting the surface. The contact implant 60 may then be formed which provides the conductive connection to the overlying metal layer 70.

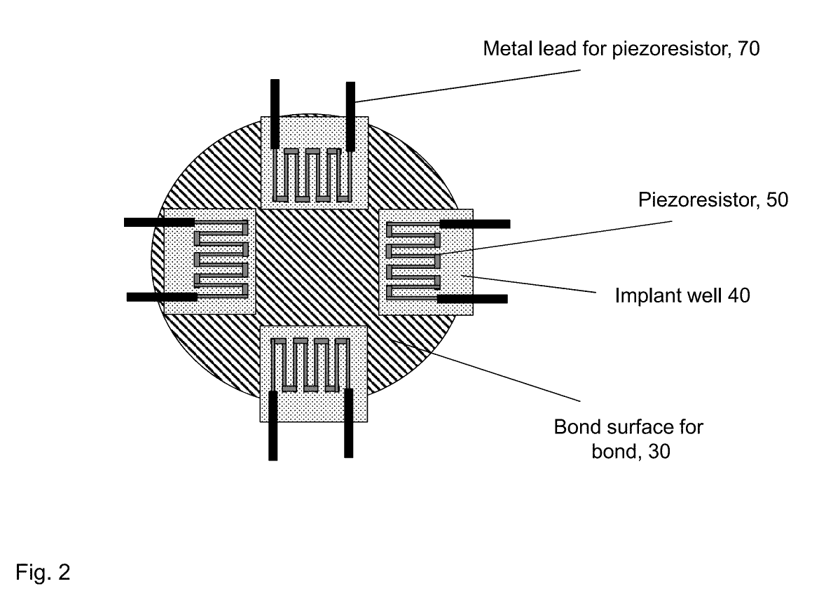

A simplified plan view diagram of the sensing structure of the self-sensing actuator is shown in FIG. 2. FIG. 2 shows the bonding surface 30 along with the piezoresistive elements 50 and metal leads 70. FIG. 2 also shows the implant wells 40 which are formed deeper in the surface. As shown in FIG. 2, the piezoresistive elements may be formed in a serpentine pattern with a number of back-and-forth loops contained therein. This may extend the overall path length of the conductive material, without taking up a large amount of wafer area, and thus improve the signal-to-noise ratio of the measurement. The number of serpentines may be in the single digits for example less than 10. The total lateral extent of the serpentine maybe on the order of about 10 to 100 μm. Accordingly, the piezoresistive element may be formed in a serpentine shape to gain more strain sensitivity. A plurality of piezoresistive elements may also be arranged in a Wheatstone bridge to eliminate low frequency sources of error such as temperature dependence of the resistivity of a metal layer 70.

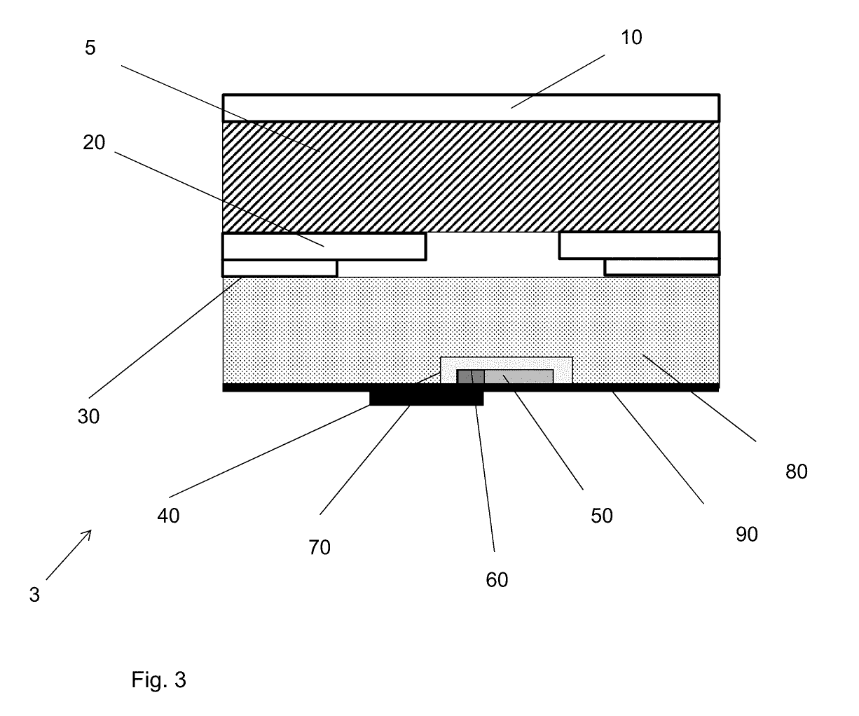

FIG. 3 is a simplified cross-sectional view of another exemplary embodiment 3 of the integrated actuator and sensor device, or self-sensing actuator. As before, the integrated actuator device comprises a first surface 1, which supports the actuator structure, and a second surface to which supports the sensor structure. The actuator structure may further include a top electrode 10 and a bottom electrode 20, between which is sandwiched a piezoelectric material, 5.

The second surface 2 may further include a bottom bonding material 30 and a semiconductor substrate 80. The second substrate may also include piezoresistive element 50, and contact implant 60, as well as metal lead structure 70. However, in the case of this embodiment, the piezoresistive implant 50, the contact implant 60, and the metal structure 70 may be located on the underside of the second surface 2, the sensor substrate. The piezoresistive elements of the sensor may be located on the bottom side of substrate, facing away from the actuator substrate 1. This embodiment may have advantageous characteristics, including a larger distance from the neutral axis such that the transduction is higher. Also, as the sensor leads are not located directly adjacent the bottom electrode which, together with the top electrode, may be driving the PZT actuator, there may be less noise picked up by the sensor.

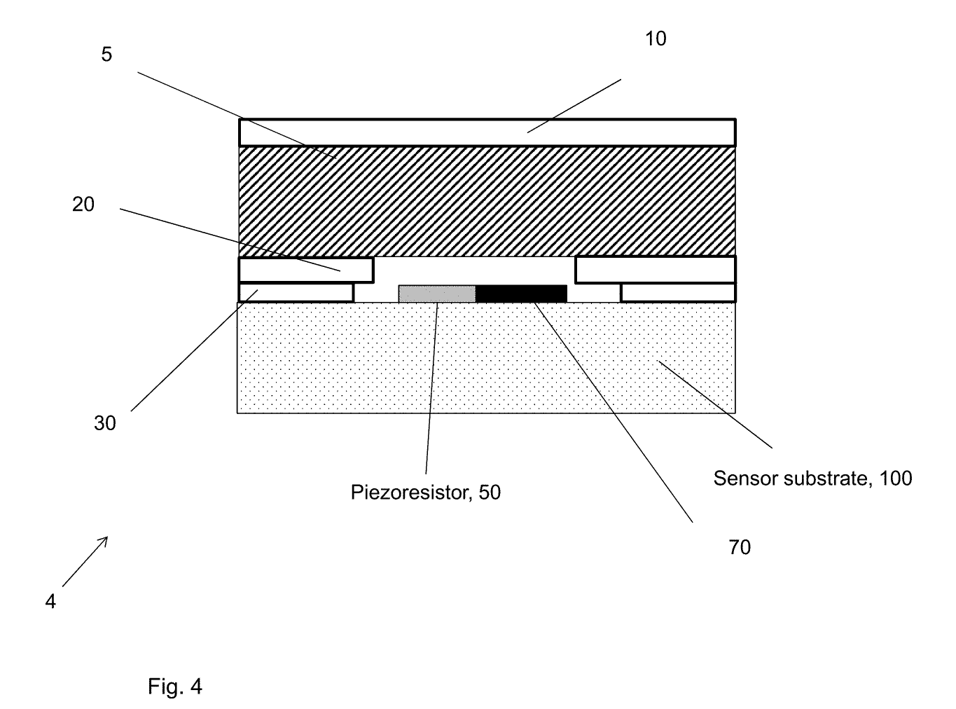

FIG. 4 is a simplified cross-sectional diagram and yet another embodiment 4 of the integrated actuator and sensor device. As shown in FIG. 4, the self-sensing actuator 4 may again include a first actuator surface 1, and a second sensor surface, 2. As before, the first surface 1 may include a top electrode 10 and a bottom electrode 20, between which a piezoelectric element 5 may be disposed. This piezoelectric element 5 may deform when the top electrode 10 and bottom electrode 20 have a voltage applied between them.

In this embodiment 4, the bottom surface 2 may be a ceramic, or glass substrate 100 rather than a semiconductor substrate as was shown earlier. In this embodiment, therefore, there may be no doping or well formation as was the case in the previous embodiments. Instead, in this embodiment, the piezoresistive elements may be simply deposited on the surface of the sensor surface 100. In this case, the piezoresistive element may be formed of essentially any metallic material which displays the piezoresistive property. This piezoresistive element is shown as element 50 in FIG. 4. As before, the piezoresistive element 50 may have electrical access provided by a metal structure 70. The advantages of this embodiment may include a wider choice of substrate materials, and superior signal-to-noise performances, as the sensor structure is fabricated on an insulating substrate.

Examples of metals which may be used as the piezoresistive element 50 include silicon, nickel and vanadium dioxide. Accordingly, the piezoresistive layer may comprise a metal on the surface of the bottom substrate, and that metal may be nickel, for example.

Accordingly, a microfabricated self-sensing actuator is disclosed, which may comprise a first substrate on which a microfabricated actuator is formed, wherein the microfabricated actuator has a portion capable of motion, and a second substrate on which a sensing structure is formed, wherein the sensing structure senses the motion of the microfabricated actuator formed on the first substrate; and wherein the first substrate is bonded to the second substrate to form a substrate pair, by a bonding material deposited on at least one of the first and the second substrate. The first substrate may be lead zirconium titanate (PZT). The second substrate may be silicon and the sensor may be a piezoresistive structure formed in the silicon substrate by implantation. The second substrate may alternatively be glass and the sensor is a piezoresistive structure deposited on the glass substrate.

The sensing structure may be located on an obverse side of the second substrate, wherein the obverse side does not have bonding material deposited thereon. The first substrate may be a PZT material with gold electrodes formed on both sides of the PZT material as electrodes. The sensing structure may be configured as a Wheatstone bridge.

The sensing structure may be formed at least 100 microns away from a neutral axis. The bonding materials may comprise at least one of gold, gold/indium and gold/nickel and gold/palladium, for example. The sensing structure may be formed by ion implantation of boron, phosphorous or arsenic. The sensing structure may have a serpentine shape, and may be configured as a Wheatstone bridge using a plurality of such serpentine shapes.

Furthermore, a method of making a microfabricated self-sensing actuator is disclosed, which may comprise forming an actuator on a first substrate, forming a top and a bottom electrode on the actuator, forming a sensing structure on a second substrate, and bonding the first substrate to the second substrate with a bonding material to form a substrate pair, wherein the sensing structure senses the motion of the microfabricated actuator. In this method, the first substrate may comprise lead zirconium titanate (PZT), and the second substrate may be silicon, wherein the sensor is a piezoresistive structure formed in the silicon substrate by implantation. In an alternative method, the second substrate may be glass and the sensor may be a piezoresistive structure deposited on the glass substrate.

The sensing structure may be located on an obverse side of the second substrate, wherein the obverse side does not have bonding material deposited thereon. The first substrate may be a PZT material with gold electrodes formed on both sides of the PZT material as electrodes. In this method, the sensing structure may be a Wheatstone bridge, and may be formed at least 100 microns away from a neutral axis.

It should be understood that designations such as “top”, “bottom”, “first” and “second” are arbitrary, and that the self-sensing device may be operated in any orientation, and fabricated in any order. Top and bottom may simply refer to obverse sides of the device, for example. The term “substrate” should be understood to include supporting layers and surfaces in general, rather than simply a standard semiconductor wafer. For example, a first substrate may include a supporting structure with a layer of PZT formed thereon.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Accordingly, the exemplary implementations set forth above, are intended to be illustrative, not limiting.

What is claimed is:

1. A microfabricated self-sensing actuator, comprising:
a first substrate on which a microfabricated actuator is formed, wherein the microfabricated actuator has a portion capable of motion;
a second substrate on which a sensing structure is formed, wherein the sensing structure senses the motion of the microfabricated actuator formed on the first substrate, and wherein the first substrate is bonded to the second substrate to form a substrate pair, by a bonding material deposited on at least one of the first and the second substrate.

2. The microfabricated self-sensing actuator of claim 1, wherein the first substrate comprises a layer of lead zirconium titanate (PZT), and further comprising a top and a bottom electrode formed on either side of the layer of lead zirconium titanate.

3. The microfabricated self-sensing actuator of claim 1, wherein the second substrate is silicon and sensing structure is a piezoresistive structure formed in the silicon substrate by implantation.

4. The microfabricated self-sensing actuator of claim 1, wherein the second substrate is glass and the sensing structure is a piezoresistive structure deposited on the glass substrate.

5. The microfabricated self-sensing actuator of claim 1, wherein the sensing structure is located on obverse side of the second substrate, wherein the obverse side does not have bonding material deposited thereon.

6. The microfabricated self-sensing actuator of claim 1, wherein the first substrate is a PZT material with gold electrodes formed on both sides of the PZT material as electrodes.

7. The microfabricated self-sensing actuator of claim 1, wherein the sensing structure comprises a Wheatstone bridge.

8. The microfabricated self-sensing actuator of claim 1, wherein the sensing structure is formed at least 100 microns away from a neutral axis.

9. The microfabricated self-sensing actuator of claim 1, wherein the bonding material comprises at least one of gold, gold/indium and gold/something else.

10. The microfabricated self-sensing actuator of claim 1, wherein the sensing structure is formed by ion implantation of boron, phosphorous or arsenic.

11. The microfabricated self-sensing actuator of claim 1, wherein the sensing structure has a serpentine shape.

12. The microfabricated self-sensing actuator of claim 11, wherein the sensing structure comprises a Wheatstone bridge configured from a plurality of serpentine shapes.

13. A method of making a microfabricated self-sensing actuator, comprising:
forming an actuator on a first substrate;
forming a sensing structure on a second substrate; and
bonding the first substrate to the second substrate with a bonding material to form a substrate pair;
wherein the sensing structure senses the motion of the microfabricated actuator formed on the first substrate.

14. The method of making the microfabricated self-sensing actuator of claim 13, further comprising:
forming a top and a bottom electrode on the actuator.

15. The method of making the microfabricated self-sensing actuator of claim 13, wherein the first substrate is lead zirconium titanate (PZT), and wherein the second substrate is silicon and the sensor is a piezoresistive structure formed in the silicon substrate by implantation.

16. The method of making the microfabricated self-sensing actuator of claim 13, wherein the second substrate is glass and the sensor comprises a piezoresistive structure deposited on the glass substrate.

17. The method of making the microfabricated self-sensing actuator of claim 13, wherein the sensing structure is located on obverse side of the second substrate, wherein the obverse side does not have bonding material deposited thereon.

18. The method of making the microfabricated self-sensing actuator of claim 13, wherein the first substrate is a lead zirconium titanate (PZT) material with gold electrodes formed on both sides of the lead zirconium titanate (PZT) material as electrodes.

19. The method of making the microfabricated self-sensing actuator of claim 13, wherein the sensing structure comprises a Wheatstone bridge.

20. The method of making the microfabricated self-sensing actuator of claim 13, wherein forming the sensing structure comprises forming the sensing structure at least 100 microns away from a neutral axis.
